(19) United States
(12) Patent Application Publication
(10) Pub. No.: US 2026/0018500 A1
(43) Pub. Date: Jan. 15, 2026

(54) SEMICONDUCTOR PACKAGE AND METHOD OF FABRICATING THE SAME

(71) Applicant: Samsung Electronics Co., Ltd., Suwon-si, Gyeonggi-do (KR)

(72) Inventors: Wooyoung KIM, Suwon-si (KR); Kyung Don MUN, Suwon-si (KR)

(73) Assignee: Samsung Electronics Co., Ltd., Suwon-si, Gyeonggi-do (KR)

(21) Appl. No.: 19/050,521

(22) Filed: Feb. 11, 2025

(30) Foreign Application Priority Data
Jul. 11, 2024 (KR) 10-2024-0091590

(51) Int. Cl. H01L 23/498; H01L 21/48; H01L 23/31

(52) U.S. Cl. CPC H01L 23/49811; H01L 21/4853; H01L 23/3128; H01L 23/49838

(57) ABSTRACT

Disclosed are semiconductor packages and their fabrication methods. The semiconductor package includes a first substrate, a semiconductor device on the first substrate, a mold layer that covers the first substrate and the semiconductor device, a second substrate on the mold layer, and a mold via that penetrates the mold layer and connects the first substrate to the second substrate. The mold via has an upper sidewall and a lower sidewall. A surface roughness of the upper sidewall is greater than a surface roughness of the lower sidewall.

### CROSS-REFERENCE TO RELATED APPLICATION

This U.S. nonprovisional application claims priority under 35 U.S.C. § 119 to Korean Patent Application No. 10-2024-0091590 filed on Jul. 11, 2024 in the Korean Intellectual Property Office, the disclosure of which is hereby incorporated by reference in its entirety.

### BACKGROUND

The present disclosure relates to a semiconductor package and a method of fabricating the same.

A semiconductor package is provided to implement an integrated circuit chip to qualify for use in electronic products. A semiconductor package is typically configured such that a semiconductor chip is mounted on a printed circuit board (PCB) and bonding wires or bumps are used to electrically connect the semiconductor chip to the printed circuit board. With the development of electronic industry, many studies have been conducted to improve the reliability and durability of semiconductor packages.

### SUMMARY

Some embodiments consistent with the present disclosure provide a semiconductor package with increased reliability.

Some embodiments consistent with the present disclosure provide a method of fabricating a semiconductor package, which method is capable of increasing a yield.

According to some embodiments consistent with the present disclosure, a semiconductor package may include: a first substrate; a semiconductor device on the first substrate; a mold layer that covers the first substrate and the semiconductor device; a second substrate on the mold layer; and a mold via that penetrates the mold layer and connects the first substrate to the second substrate. The mold via may have an upper sidewall and a lower sidewall. A surface roughness of the upper sidewall may be greater than a surface roughness of the lower sidewall.

According to some embodiments consistent with the present disclosure, a semiconductor package may include: a first substrate; a semiconductor device on the first substrate; a mold layer that covers the first substrate and the semiconductor device; a second substrate on the mold layer; and a mold via that penetrates the mold layer and connects the first substrate to the second substrate. The mold via may have an upper sidewall, a middle sidewall, and a lower sidewall. The middle sidewall is not aligned with the upper sidewall or the lower sidewall.

According to some embodiments consistent with the present disclosure, a semiconductor package may include: a first redistribution substrate; a semiconductor device on the first redistribution substrate; a mold layer that covers the first redistribution substrate and the semiconductor device; a second redistribution substrate on the mold layer; and a mold via that penetrates the mold layer and connects the first redistribution substrate to the second redistribution substrate. The first redistribution substrate may include: a plurality of first redistribution dielectric layers that are stacked on each other; and a first conductive pad and a second conductive pad on an uppermost one of the first redistribution dielectric layers. The first conductive pad may be connected to the semiconductor device. The second conductive pad may be in contact with the mold via. The first conductive pad may have a first width. The second conductive pad may have a second width greater than the first width. The second redistribution substrate may include: a plurality of second redistribution dielectric layers that are stacked on each other; and a second redistribution pattern that penetrates a lowermost one of the second redistribution dielectric layers to come into contact with the mold via.

According to some embodiments consistent with the present disclosure, a method of fabricating a semiconductor package may include: forming a first substrate that includes a first conductive pad and a second conductive pad; forming a first photoresist layer on the first substrate; forming a second photoresist layer on the first photoresist layer; patterning the first photoresist layer and the second photoresist layer to form a mold via hole that exposes the second conductive pad; forming a mold via in the mold via hole; removing the second photoresist layer; performing a roughness formation process on a top surface and an upper sidewall of the mold via; removing the first photoresist layer to expose the first substrate; mounting a semiconductor device on the first substrate; and forming a mold layer that covers the first substrate, the semiconductor device, and the mold via. According to some embodiments consistent with the present disclosure, before forming the second photoresist layer, the method may further include forming a protection layer on the first photoresist layer, wherein removing the second photoresist layer includes exposing a top surface of the protection layer. According to some embodiments consistent with the present disclosure, the method may further include grinding the mold layer to expose the mold via, wherein the grinding causes a decrease in surface roughness of a top surface of the mold via.

### BRIEF DESCRIPTION OF DRAWINGS

FIG. 1 illustrates a plan view showing a semiconductor package according to some embodiments consistent with the present disclosure.

FIG. 2 illustrates a cross-sectional view taken along line A-A′ of FIG. 1 according to some embodiments consistent with the present disclosure.

FIGS. 3A to 3C illustrate enlarged views showing section P1 of FIG. 2 according to some embodiments consistent with the present disclosure.

FIGS. 4A to 4L illustrate cross-sectional views showing a method of fabricating a semiconductor package of FIG. 2 according to some embodiments consistent with the present disclosure.

FIGS. 5A and 5B illustrate enlarged views showing section P2 of FIG. 4C according to some embodiments consistent with the present disclosure.

FIGS. 6A to 6C illustrate cross-sectional views showing a method of fabricating a semiconductor package according to some embodiments consistent with the present disclosure.

FIG. 7 illustrates an enlarged view showing section P2 of FIG. 6B according to some embodiments consistent with the present disclosure.

FIG. 8A illustrates a cross-sectional view showing a semiconductor package according to some embodiments consistent with the present disclosure.

FIG. 8B illustrates an enlarged view showing section P1 of FIG. 8A according to some embodiments consistent with the present disclosure.

FIG. 9A illustrates a cross-sectional view showing a semiconductor package according to some embodiments consistent with the present disclosure.

FIG. 9B illustrates an enlarged view showing section P1 of FIG. 9A according to some embodiments consistent with the present disclosure.

FIG. 10 illustrates a cross-sectional view showing a semiconductor package according to some embodiments consistent with the present disclosure.

FIG. 11 illustrates a cross-sectional view showing a semiconductor package according to some embodiments consistent with the present disclosure.

### DETAILED DESCRIPTION

Some embodiments consistent with the present disclosure will now be described in detail with reference to the accompanying drawings to aid in clearly explaining the present disclosure. In this description, such terms as “first” and “second” may be used to simply distinguish identical or similar components from each other, and the sequence of such terms may be changed in accordance with the order of mention.

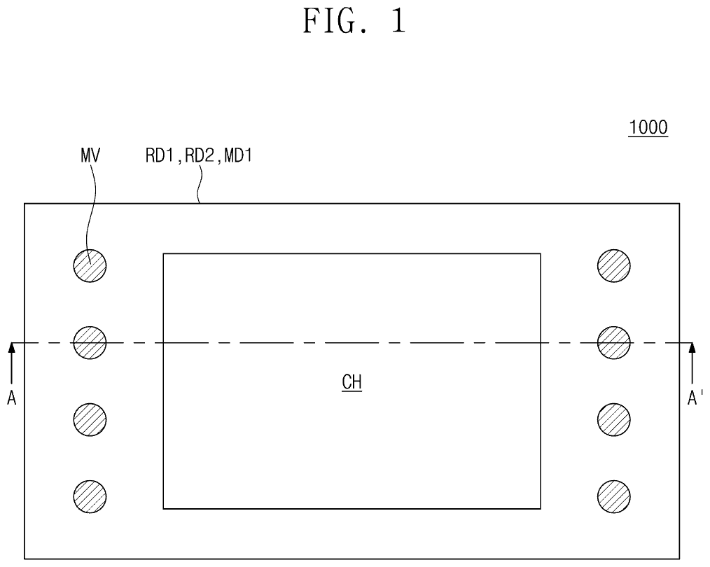

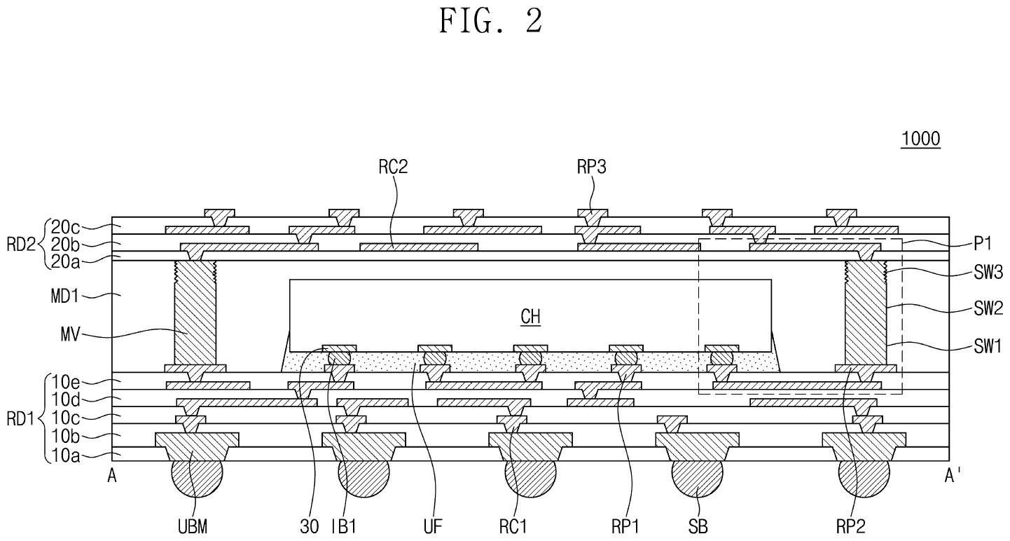

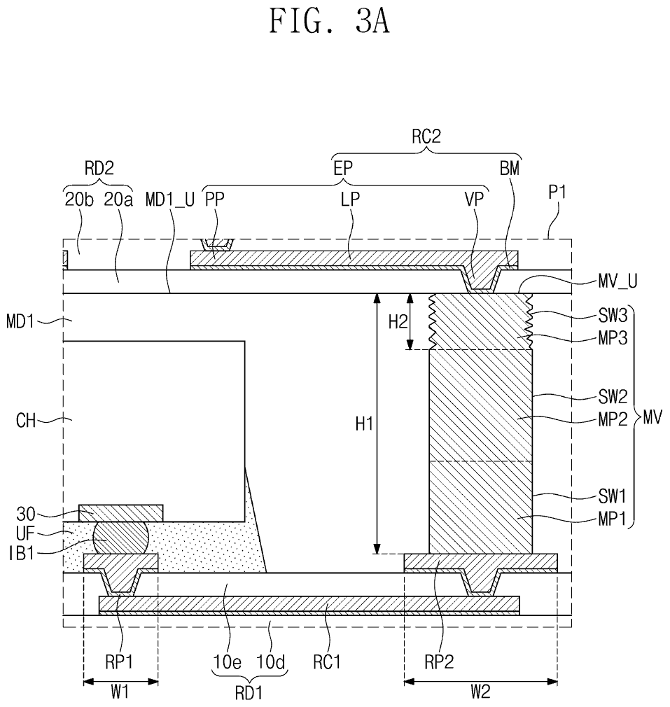

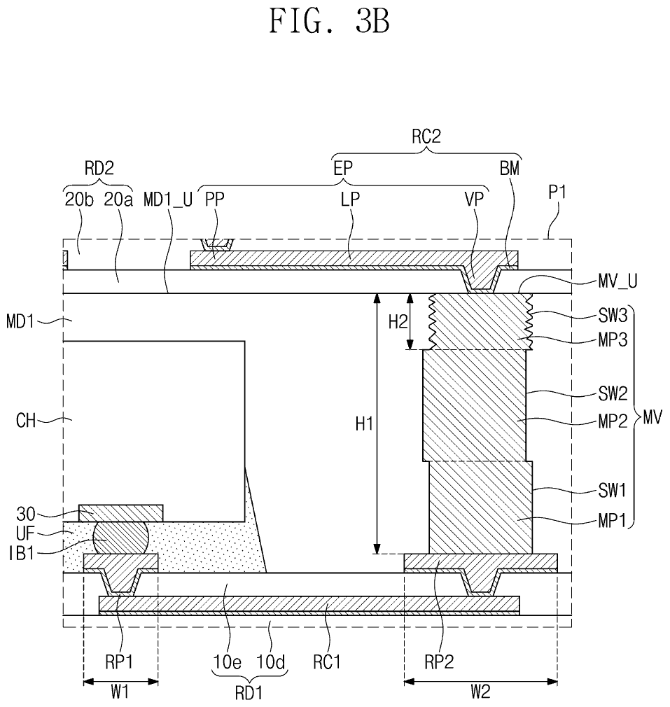

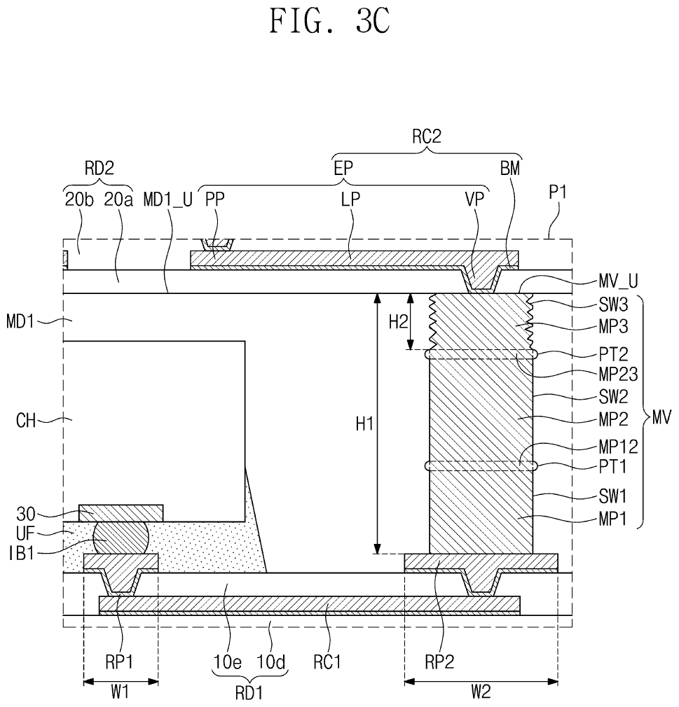

FIG. 1 illustrates a plan view showing a semiconductor package 1000 according to some embodiments consistent with the present disclosure. FIG. 2 illustrates a cross-sectional view taken along line A-A′ of FIG. 1 according to some embodiments consistent with the present disclosure. FIGS. 3A to 3C illustrate enlarged views showing section P1 of FIG. 2 according to some embodiments consistent with the present disclosure.

Referring to FIGS. 1 and 2, a semiconductor package 1000 may include a first substrate RD1, a semiconductor device CH, a first mold layer MD1, a second substrate RD2, and mold vias MV. Each of the first substrate RD1 and the second substrate RD2 may be a redistribution substrate or a double-sided or multi-layered printed circuit board. The first substrate RD1 may be called a first redistribution substrate, and the second substrate RD2 may be called a second redistribution substrate. The first substrate RD1 may include first dielectric layers 10a to 10e, under bumps UBM, first substrate inner patterns RC1, and first and second conductive pads RP1 and RP2. The first dielectric layers 10a to 10e may each be, for example, a photo-imageable dielectric (PID). Although five first dielectric layers 10a to 10e have been disclosed above, first substrate RD1 may include any number of first dielectric layers.

The under bumps UBM, the first substrate inner patterns RC1, and the first and second conductive pads RP1 and RP2 may each be formed of a conductive material. The under bumps UBM, the first substrate inner patterns RC1, and the first and second conductive pads RP1 and RP2 may each include at least one metal selected from titanium, titanium nitride, tantalum, tantalum nitride, copper, aluminum, nickel, and gold.

The under bumps UBM may penetrate a lowermost layer 10a of the first dielectric layers 10a to 10e. The under bumps UBM may be provided thereon with external connection terminals SB bonded thereto. The external connection terminals SB may be, for example, at least one of solder balls, conductive bumps, and conductive pillars. The external connection terminals SB may include, for example, at least one metal selected from tin, nickel, silver, copper, gold, and aluminum.

The first substrate inner patterns RC1 may be interposed between the first dielectric layers 10a to 10e, and may penetrate some of the first dielectric layers 10a to 10e. The first and second conductive pads RP1 and RP2 may be positioned on and penetrate an uppermost layer 10e of the first dielectric layers 10a to 10e.

The second substrate RD2 may include second dielectric layers 20a to 20c, second substrate inner patterns RC2, and third conductive pads RP3. The second dielectric layers 20a to 20c may each be, for example, a photo-imageable dielectric (PID). Although three second dielectric layers 20a to 20c have been disclosed above, second substrate RD2 may include any number of second dielectric layers. The second substrate inner patterns RC2 and the third conductive pads RP3 may each be formed of a conductive material. The second substrate inner patterns RC2 and the third conductive pads RP3 may each include at least one metal selected from titanium, titanium nitride, tantalum, tantalum nitride, copper, aluminum, nickel, and gold.

Referring to FIG. 3A, the first substrate inner patterns RC1 and the second substrate inner patterns RC2 may each include a diffusion break layer BM and a wiring part EP. The diffusion break layer BM may cover a bottom surface of the wiring part EP. The diffusion break layer BM may include at least one metal selected from titanium, titanium nitride, tantalum, and tantalum nitride. The wiring part EP may include metal, such as one or more of copper, aluminum, nickel, and gold. The first substrate inner patterns RC1 and the second substrate inner patterns RC2 may each include a via part VP that penetrates one of the first and second dielectric layers 10a to 10e and 20a to 20c, and may also each include a line part LP and a pad part PP on the via part VP. The via part VP may have a width that decreases in a downward direction (e.g., direction extending from second substrate RD2 towards first substrate RD1). The first substrate inner patterns RC1 and the second substrate inner patterns RC2 may each be called a redistribution pattern.

Referring to FIGS. 1 to 3A, each of the first, second, and third conductive pads RP1, RP2, and RP3 may also include a diffusion break layer BM. The first conductive pads RP1 may be disposed on a central portion of the first substrate RD1, and may overlap with (e.g., be located under) the semiconductor device CH. The second conductive pads RP2 may be disposed on an edge of the first substrate RD1, and may be correspondingly in contact with the mold vias MV. Like the first substrate inner patterns RC1 and the second substrate inner patterns RC2, each of the first and second conductive pads RP1 and RP2 may include a via part VP and a pad part PP. Each of the first and second conductive pads RP1 and RP2 may be called a redistribution pad. Each of the first conductive pads RP1 may have a first width W1. Each of the second conductive pads RP2 may have a second width W2 greater than the first width W1.

The semiconductor device CH may be called a semiconductor chip or a semiconductor die. The semiconductor device CH may be one of a microelectromechanical system (MEMS) device chip, an application specific integrated circuit (ASIC) chip, and a memory device chip such as Flash memory, DRAM, SRAM, EEPROM, PRAM, MRAM, ReRAM, high bandwidth memory (HBM), and hybrid memory cube (HMC). The semiconductor device CH may include chip conductive pads 30 on a lower end thereof.

First inner connection members IB1 may be interposed and connect the chip conductive pads 30 and the first conductive pads RP1. The first inner connection members IB1 may be, for example, at least one of solder balls, conductive bumps, and conductive pillars. The first inner connection members IB1 may include, for example, at least one metal selected from tin, nickel, silver, copper, gold, and aluminum.

An underfill layer UF may be interposed between the semiconductor device CH and the first substrate RD1. The underfill layer UF may be formed of a non-conductive film (NCF). The underfill layer UF may include a thermosetting resin or a photo-curable resin. The underfill layer UF may further include organic fillers or inorganic fillers. The organic fillers may include, for example, a polymeric material. The inorganic fillers may include, for example, silicon oxide (SiO₂).

The first mold layer MD1 may cover the semiconductor device CH and the first substrate RD1. The first mold layer MD1 may include a dielectric resin, such as an epoxy molding compound (EMC). The first mold layer MD1 may further include fillers, and the fillers may be dispersed in the dielectric resin.

Referring to FIG. 3A, each of the mold vias MV may penetrate the first mold layer MD1. The mold vias MV may electrically connect the first substrate RD1 to the second substrate RD2. Each of the mold vias MV may include a lower part MP1, an upper part MP3, and a middle part MP2 between the lower and upper parts MP1 and MP3, which lower, middle, and upper parts MP1, MP2, and MP3 are connected into a single unitary piece. Each of the mold vias MV may have a lower sidewall SW1, an upper sidewall SW3, and a middle sidewall SW2 between the lower and upper sidewalls SW1 and SW3, which lower, middle, and upper sidewalls SW1, SW2, and SW3 are connected into a single unitary piece. The lower sidewall SW1, the middle sidewall SW2, and the upper sidewall SW3 may be vertically aligned with each other. A surface roughness of the upper sidewall SW3 may be greater than that of at least one of the lower sidewall SW1 and the middle sidewall SW2. As used herein, the term “surface roughness” may be defined as a roughness average (Ra) of the associated surface. For example, the roughness average may measure an average deviation of a surface from a mean height of the surface determined over a length of the surface or over an area of the surface. Each of the mold vias MV may have a first vertical length H1. The upper sidewall SW3 may have a second vertical length H2. The second vertical length H2 may correspond to about 1/12 to about 11/12 of the first vertical length H1. In some embodiments, as the upper sidewall SW3 of the mold via MV has a large surface roughness, an increased adhesive force may be provided between the first mold layer MD1 and the upper sidewall SW3 of the mold via MV, thereby preventing delamination between the first mold layer MD1 and the upper sidewall SW3 of the mold via MV. Accordingly, reliability of the semiconductor package 1000 may be increased.

Referring to FIG. 3B, in some embodiments, the middle sidewall SW2 of the mold via MV may not be vertically aligned with at least one of the lower sidewall SW1 and the upper sidewall SW3 of the mold via MV. Alternatively, the lower sidewall SW1 may not be vertically aligned with at least one of the middle sidewall SW2 and the upper sidewall SW3. Other configurations may be the same as those of FIG. 3A.

Referring to FIG. 3C, in some embodiments, each of the mold vias MV may further include a first insertion MP12 between the lower part MP1 and the middle part MP2 that are connected into a single unitary piece and a second insertion MP23 between the middle part MP2 and the upper part MP3 that are connected into a single unitary piece. The first insertion MP12 and the second insertion MP23 may have their respective edges PT1 and PT2 that protrude more laterally relative to the sidewalls SW1 to SW3. That is, first insertion MP12 and/or second insertion MP23 may have a width that is greater than a width of any of lower part MP1, middle part MP2, and/or upper part MP3. Each of the edges PT1 and PT2 of the first and second insertions MP12 and MP23 may be called a protrusion. Other configurations may be the same as those of FIG. 3A.

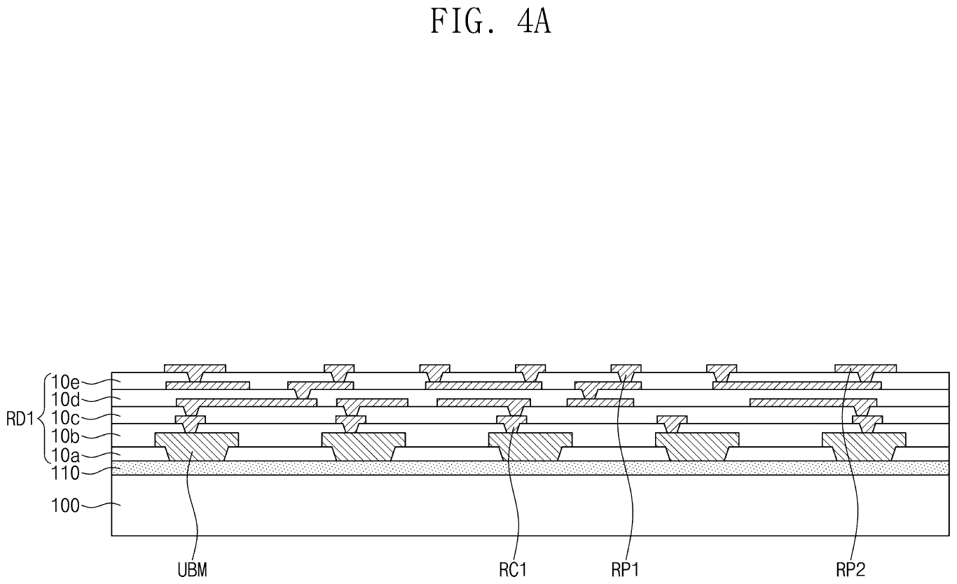

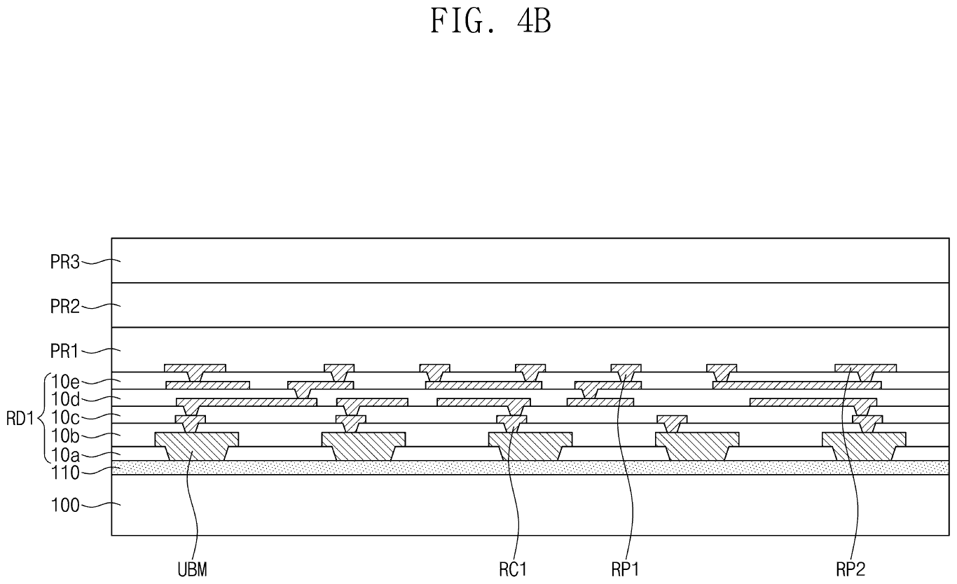

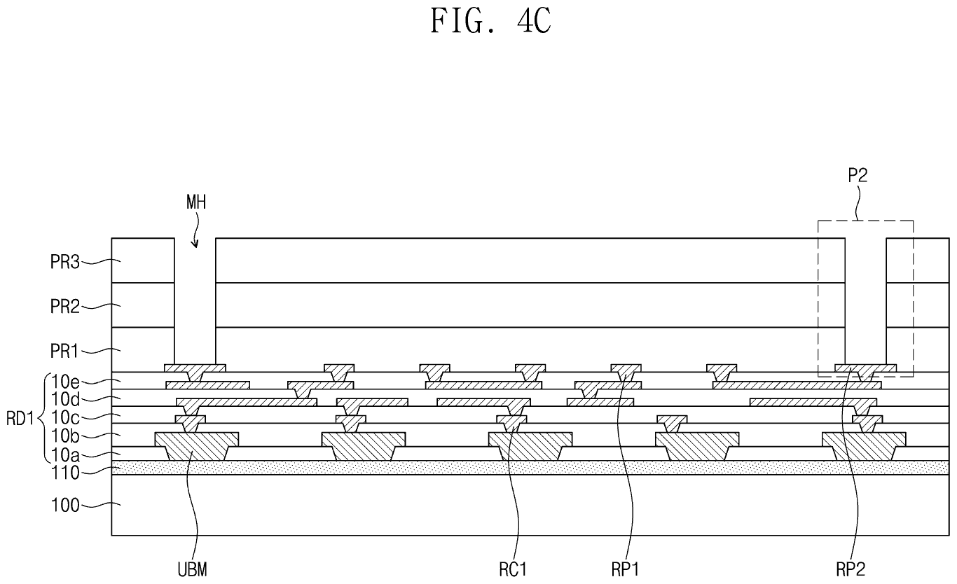

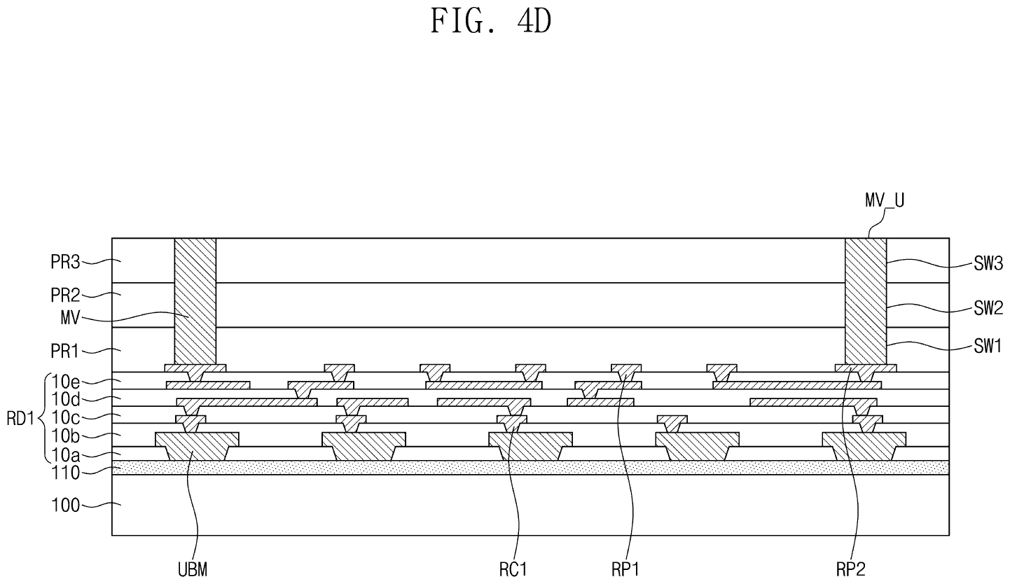

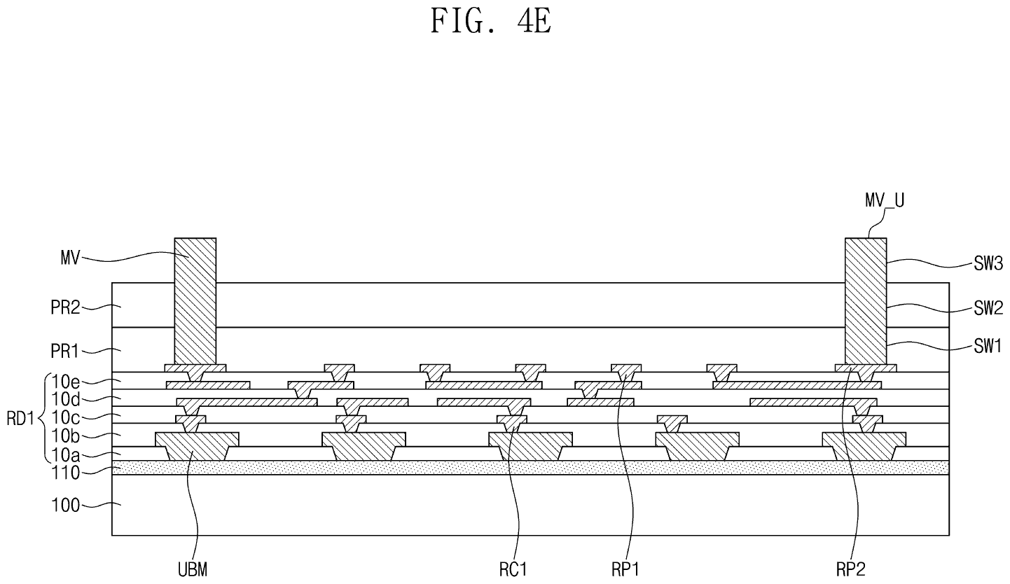

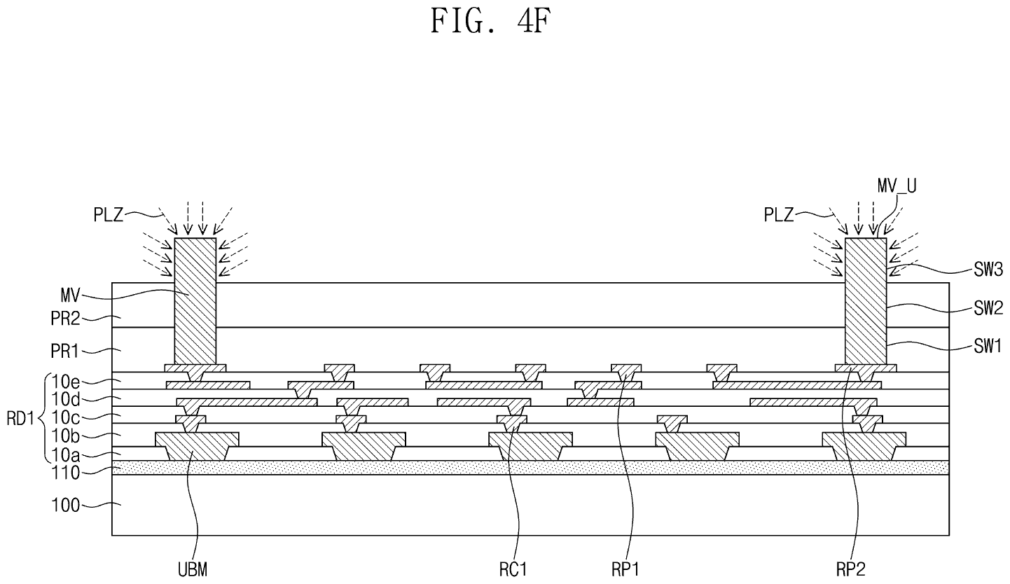

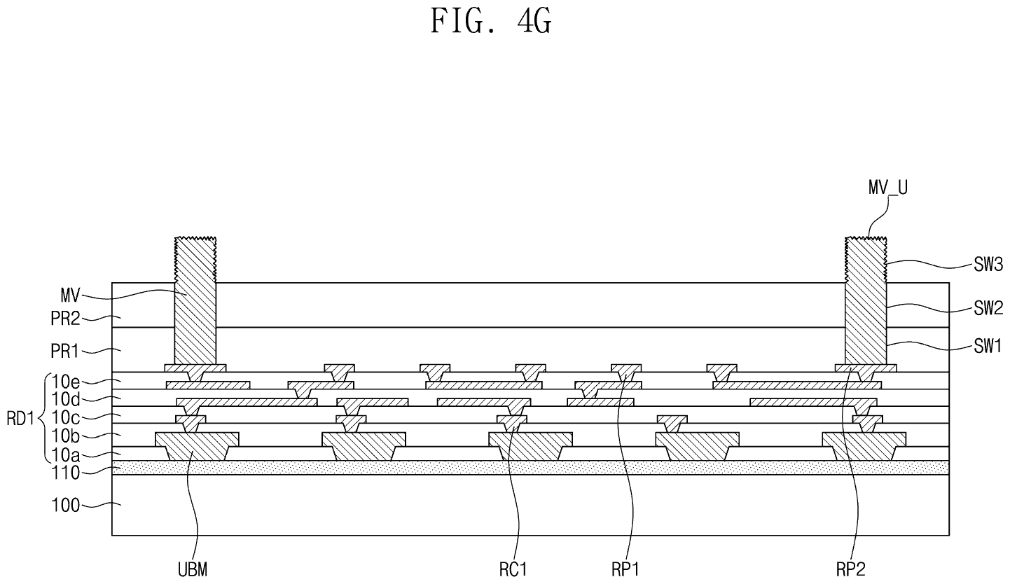

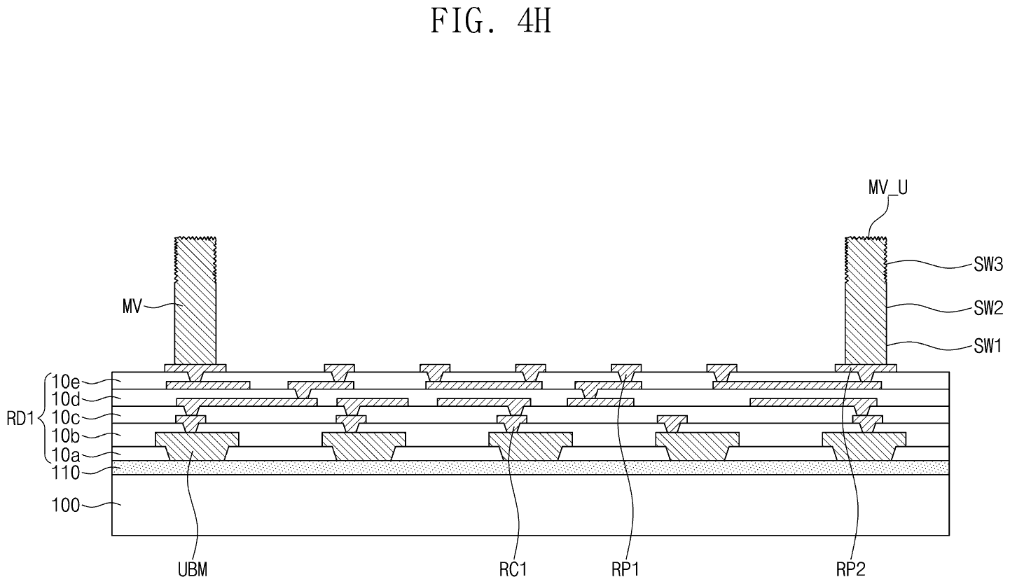

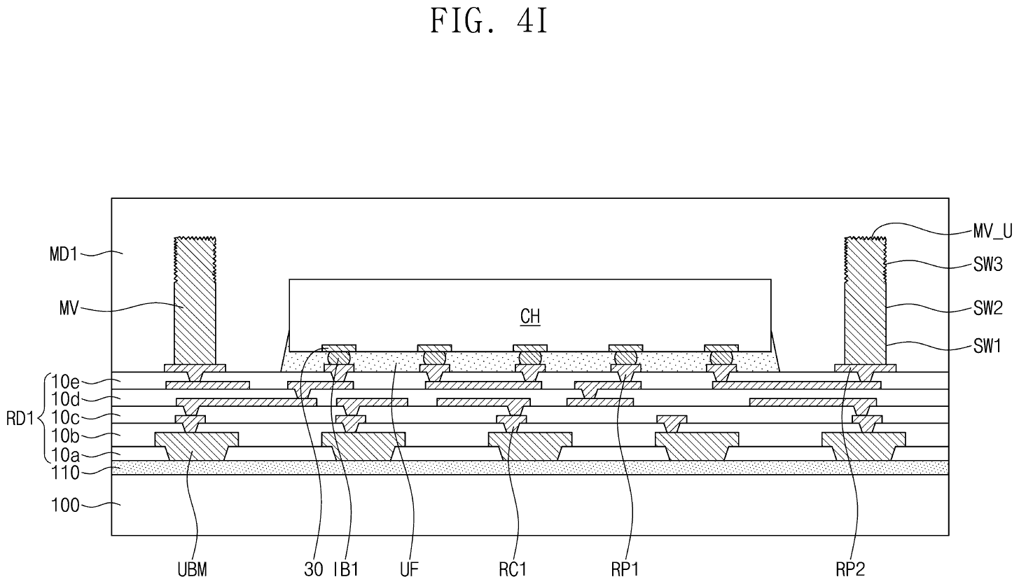

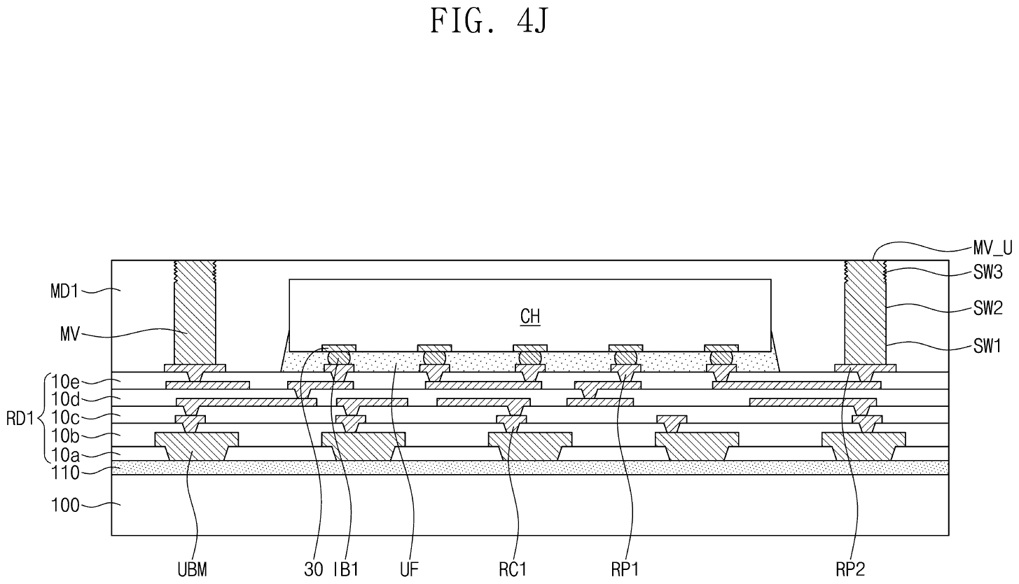

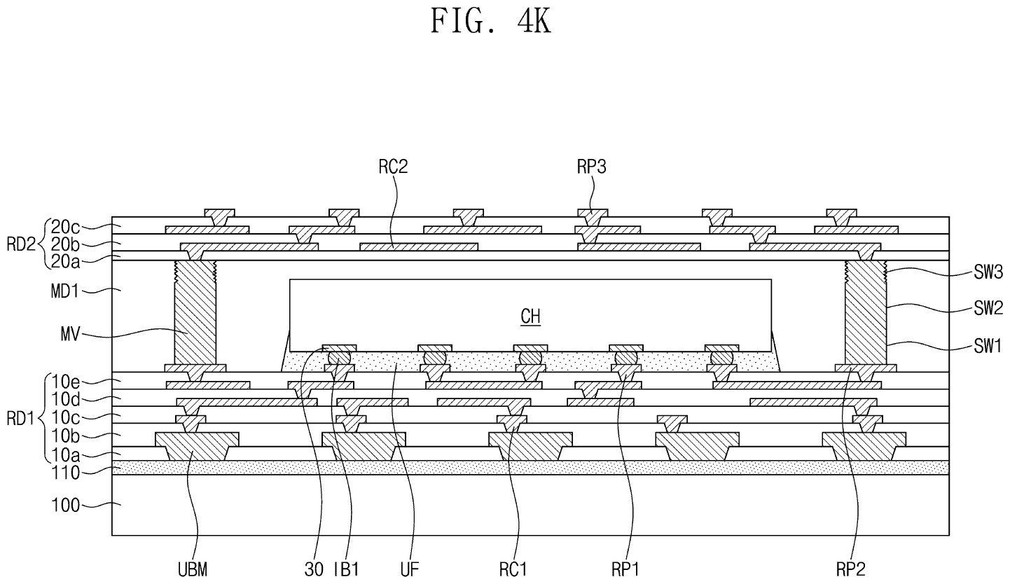

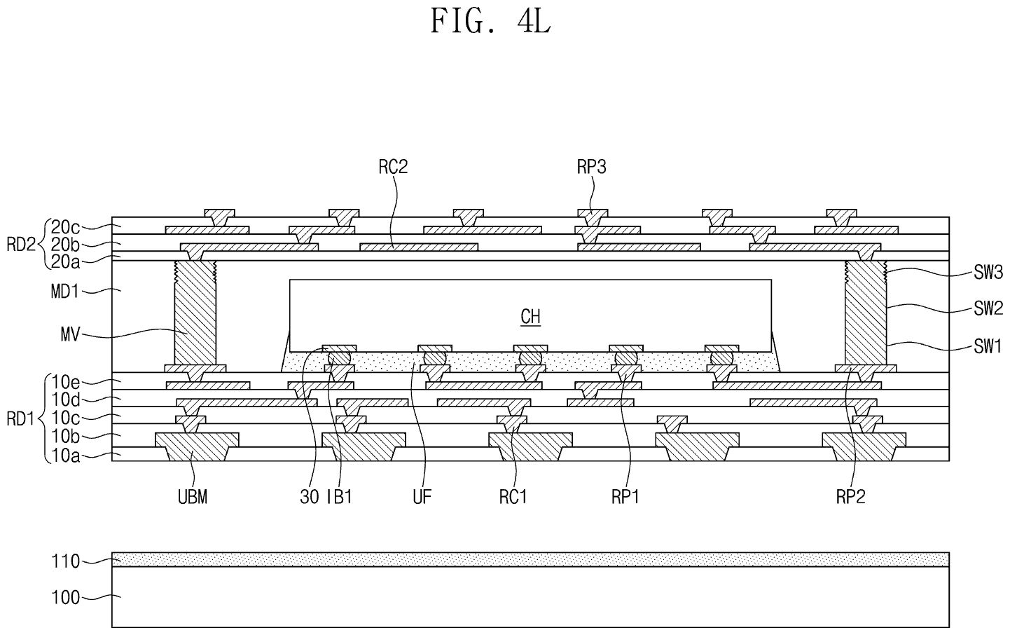

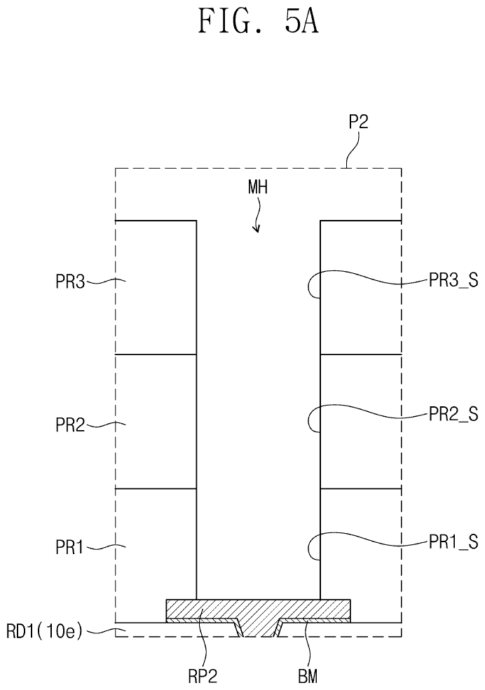

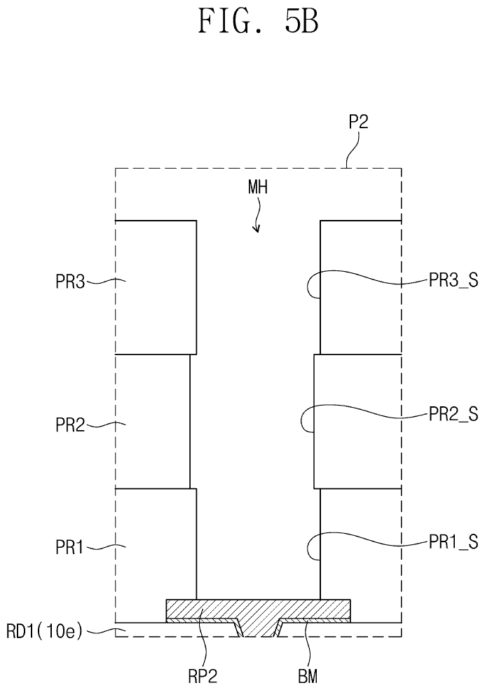

FIGS. 4A to 4L illustrate cross-sectional views showing a method of fabricating a semiconductor package of FIG. 2 according to some embodiments consistent with the present disclosure. FIGS. 5A and 5B illustrate enlarged views showing section P2 of FIG. 4C according to some embodiments consistent with the present disclosure.

Referring to FIG. 4A, a sacrificial substrate 100 may be prepared. For example, the sacrificial substrate 100 may be a tape, a transparent glass substrate, or a bare wafer. A sacrificial layer 110 may be formed on the sacrificial substrate 100. The sacrificial layer 110 may include an epoxy resin. The sacrificial layer 110 may exhibit, for example, photodegradability or thermodegradability. A first substrate RD1 may be formed on the sacrificial layer 110. The first substrate RD1 may be formed to include first dielectric layers 10a to 10e, under bumps UBM, first substrate inner patterns RC1, and first and second conductive pads RP1 and RP2. For example, the first dielectric layers 10a to 10e may each be formed of a photo-imageable dielectric (PID), and may be formed by coating, baking, exposure, and development processes. The under bumps UBM, the first substrate inner patterns RC1, and the first and second conductive pads RP1 and RP2 may be formed by a plating process. The first and second conductive pads RP1 and RP2 may be formed on an uppermost layer 10e of the first dielectric layers 10a to 10e.

Referring to FIG. 4B, first to third photoresist layers PR1 to PR3 may be sequentially stacked on the uppermost first dielectric layer 10e and the first and second conductive pads RP1 and RP2. Each of the first to third photoresist layers PR1 to PR3 may be formed by coating and baking processes. Each of the first to third photoresist layers PR1 to PR3 may be formed to have a thickness of, for example, about 100 to 120 μm. The first to third photoresist layers PR1 to PR3 are formed in three layers, but the present disclosure is not limited thereto and any number of photoresist layers may be formed. The number and thickness of the first to third photoresist layers PR1 to PR3 may depend on a vertical length of a mold via MV which is discussed elsewhere in this disclosure.

Referring to FIGS. 4C, 5A, and 5B, exposure processes and development processes may be alternately repeated to form mold via holes MH in the first to third photoresist layers PR1 to PR3. The mold via holes MH may expose top surfaces of the second conductive pads RP2.

For example, the third photoresist layer PR3 positioned at a top location may undergo a first exposure process and a first development process to form in the third photoresist layer PR3 a first opening to expose a sidewall PR3_S of the third photoresist layer PR3. Then, the second photoresist layer PR2 beneath the first opening may undergo a second exposure process and a second development process to form in the second photoresist layer PR2 a second opening to expose a sidewall PR2_S of the second photoresist layer PR2. Thereafter, the first photoresist layer PR1 beneath the second opening may undergo a third exposure process and a third development process to form in the first photoresist layer PR1 a third opening to expose a sidewall PR1_S of the first photoresist layer PR1. Thus, the first to third openings may be spatially connected to form the mold via hole MH. The reason why the exposure and development processes are carried out several times on the first to third photoresist layers PR1 to PR3 may be because it may be difficult for light to penetrate all of the first to third photoresist layers PR1 to PR3 at once.

When positional misalignment of photomasks does not occur during the exposure processes, the sidewalls PR1_S to PR3_S of the first to third photoresist layers PR1 to PR3 exposed to the mold via hole MH may be aligned with each other as shown in FIG. 5A. In this case, a mold via MV which will be formed in the mold via hole MH of FIG. 5A may have aligned sidewalls SW1 to SW3 as shown in FIG. 3A. When positional misalignment of photomasks occurs during the exposure processes, the sidewalls PR1_S to PR3_S of the first to third photoresist layers PR1 to PR3 exposed to the mold via hole MH may not be aligned with each other as shown in FIG. 5B. A mold via MV which will formed in the mold via hole MH of FIG. 5B may have a laterally shifted middle sidewall SW2 as shown in FIG. 3B.

Referring to FIGS. 4D and 5A, a plating process may be performed to form mold vias MV in the mold via holes MH. In the plating process, the top surface of the second conductive pad RP2 exposed through a bottom surface of the mold via hole MH may serve as a seed. Each of the mold vias MV may have a lower sidewall SW1, a middle sidewall SW2, an upper sidewall SW3, and a top surface MV_U. The lower sidewall SW1, the middle sidewall SW2, the upper sidewall SW3, and the top surface MV_U may each be smooth. The lower sidewall SW1 may be in contact with the sidewall PR1_S of the first photoresist layer PR1. The middle sidewall SW2 may be in contact with the sidewall PR2_S of the second photoresist layer PR2. The upper sidewall SW3 may be in contact with the sidewall PR3_S of the third photoresist layer PR3.

Referring to FIG. 4E, the third photoresist layer PR3 may be removed to expose a top surface of the second photoresist layer PR2. In this stage, the removal of the third photoresist layer PR3 may expose the smooth upper sidewall SW3 and the top surface MV_U of the mold via MV. An ashing process may be employed to remove the third photoresist layer PR3.

Referring to FIGS. 4F and 4G, the upper sidewall SW3 and the top surface MV_U of the mold via MV may undergo a roughness formation process PLZ (or CZ treatment process). In this stage, the upper sidewall SW3 and the top surface MV_U of the mold via MV may each have an increased surface roughness. The roughness formation process PLZ may be performed using an etchant or plasma. During the roughness formation process PLZ, the first and second photoresist layers PR1 and PR2 may serve to protect the first dielectric layers 10a to 10e and the first conductive pads RP1 on a surface of the first substrate RD1.

Referring to FIG. 4H, the first and second photoresist layers PR1 and PR2 may be removed to expose the first substrate RD1 and to also expose the lower sidewall SW1 and the middle sidewall SW2 of the mold via MV. An ashing process may be employed to remove the first and second photoresist layers PR1 and PR2.

Referring to FIG. 4I, first inner connection members IB1 may be used to bond a semiconductor device CH to the first conductive pads RP1 of the first substrate RD1. An underfill layer UF may be formed between the semiconductor device CH and the first substrate RD1. A first mold layer MD1 may be formed to cover the semiconductor device CH, the first substrate RD1, and the mold vias MV.

Referring to FIG. 4J, a grinding process may be performed to remove a portion of the first mold layer MD1. During the grinding process, upper portions of the mold vias MV may also be removed. Thus, the top surfaces MV_U of the mold vias MV may be exposed. The top surfaces MV_U of the mold vias MV may be coplanar with a top surface of the first mold layer MD1. The grinding process may cause a reduction in the surface roughness of the top surfaces MV_U of the mold vias MV. As the upper sidewalls SW3 of the mold vias MV have their increased surface roughness, an increased adhesive force may be provided between the first mold layer MD1 and the upper sidewalls SW3 of the mold vias MV, and therefore during the grinding process, no delamination may occur between the first mold layer MD1 and the mold vias MV.

Referring to FIG. 4K, a second substrate RD2 may be formed on the first mold layer MD1. The second substrate RD2 may include second dielectric layers 20a to 20c, second substrate inner patterns RC2, and third conductive pads RP3. For example, the second dielectric layers 20a to 20c may each be formed of a photo-imageable dielectric (PID), and may be formed by coating, baking, exposure, and development processes. The second substrate inner patterns RC2 and the third conductive pads RP3 may be formed by a plating process. As there is no delamination between the first mold layer MD1 and the mold vias MV during the grinding process, the second substrate RD2 may be manufactured without failure. Thus, a subsequently described semiconductor package 1000 may have increased reliability and yield.

Referring to FIG. 4L, the sacrificial layer 110 and the sacrificial substrate 100 may be separated from a bottom surface of the first substrate RD1. Referring to FIG. 2, external connection terminals SB may be bonded to the under bumps UBM of the first substrate RD1. A singulation process may be performed to fabricate semiconductor package 1000.

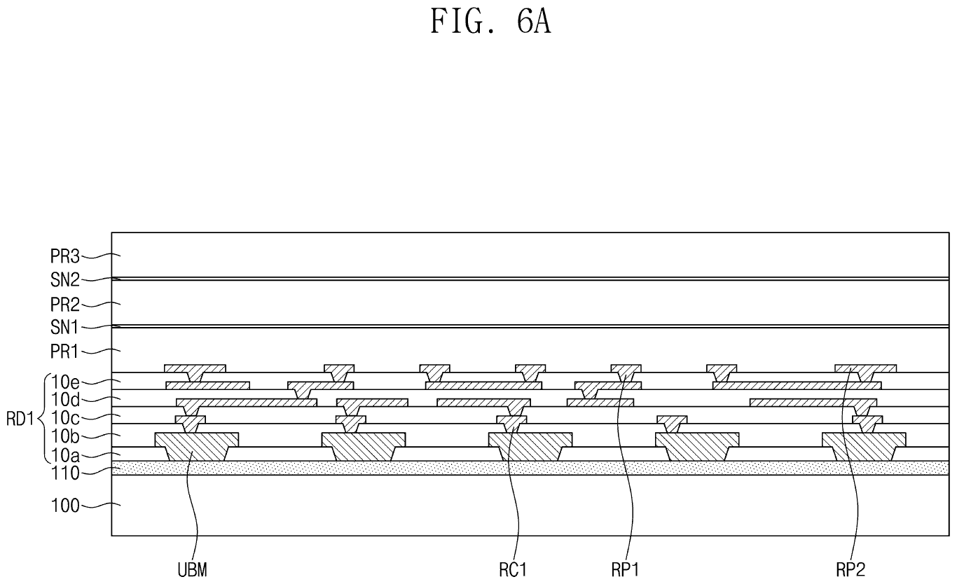

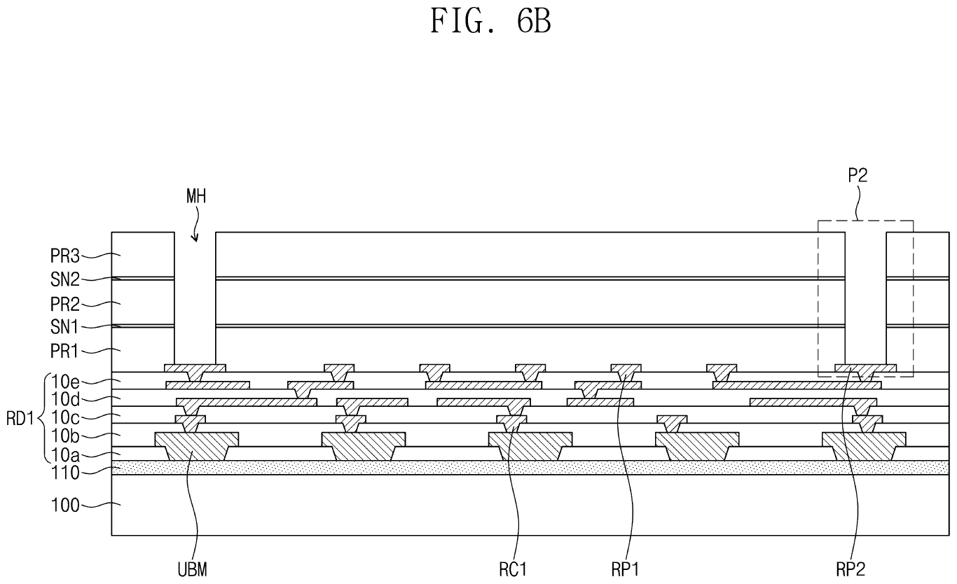

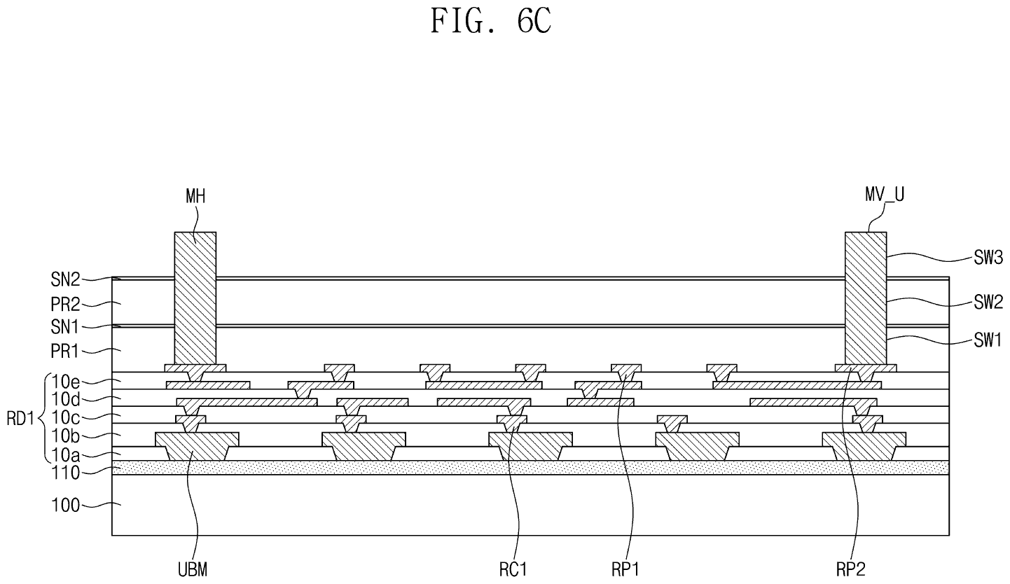

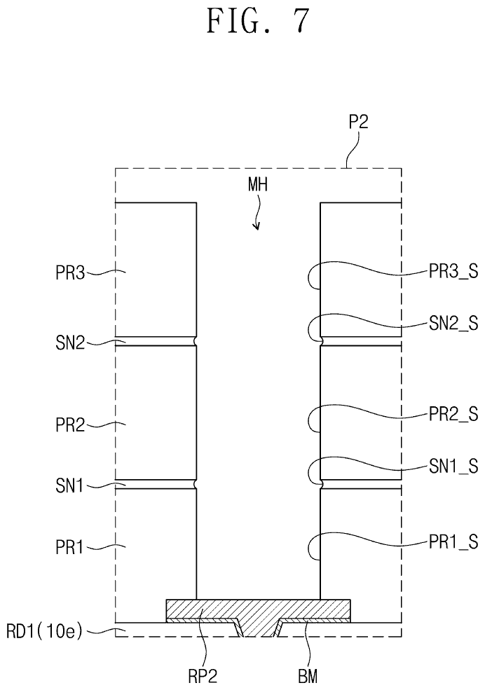

FIGS. 6A to 6C illustrate cross-sectional views showing a method of fabricating a semiconductor package according to some embodiments consistent with the present disclosure. FIG. 7 illustrates an enlarged cross-sectional view showing section P2 of FIG. 6B according to some embodiments consistent with the present disclosure.

Referring to FIG. 6A, in a state of FIG. 4A, a first photoresist layer PR1, a first protection layer SN1, a second photoresist layer PR2, a second protection layer SN2, and a third photoresist layer PR3 may be sequentially stacked on the uppermost first dielectric layer 10e and the first and second conductive pads RP1 and RP2. The protection layer SN1 and the second protection layer SN2 may each be called an antireflection layer. The first protection layer SN1 and the second protection layer SN2 may be formed of silicon oxide, silicon nitride, or a material having an etch selectivity with respect to a photoresist layer. Each of the first protection layer SN1 and the second protection layer SN2 may be formed to have a thickness less than that of each of the first to third photoresist layers PR1 to PR3.

Referring to FIGS. 6B and 7, the third photoresist layer PR3, the second protection layer SN2, the second photoresist layer PR2, the first protection layer SN1, and the first photoresist layer PR1 may be sequentially patterned to form a mold via hole MH. In this step, exposure processes and development processes may be alternately repeated to pattern the first to third photoresist layers PR1 to PR3. The first protection layer SN1 and the second protection layer SN2 may be patterned by an isotropic etching process or an anisotropic etching process. When the first protection layer SN1 and the second protection layer SN2 are patterned by an isotropic etching process, a sidewall SN1_S of the first protection layer SN1 and a sidewall SN2_S of the second protection layer SN2 may become rounded in the mold via hole MH.

Referring to FIG. 6C, the third photoresist layer PR3 may be removed to expose a top surface of the second protection layer SN2. As the second protection layer SN2 has an etch selectivity with respect to the second and third photoresist layers PR2 and PR3, the second protection layer SN2 may protect the second photoresist layer PR2 when the third photoresist layer PR3 is removed. Thus, it may be possible to more accurately adjust the required degree of exposure of the mold via MV.

Subsequently, a process identical or similar to that discussed with reference to FIGS. 4F to 4L may be performed to fabricate a semiconductor package 1000 of FIG. 2. The mold via MV may include first and second protrusions PT1 and PT2 as shown in FIG. 3C.

In some embodiments, the first protection layer SN1 may be omitted, and in this case, the mold via MV may have only the second protrusion PT2.

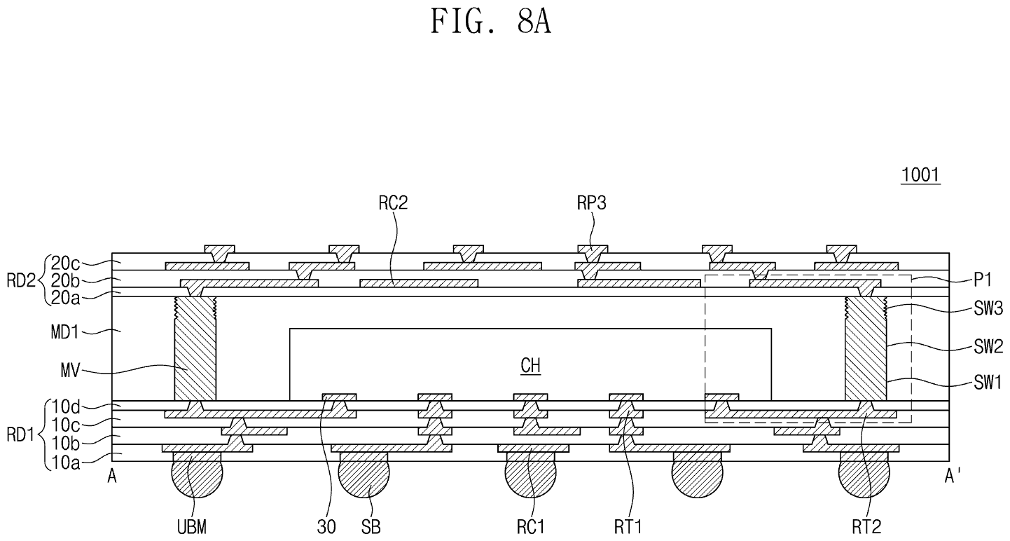

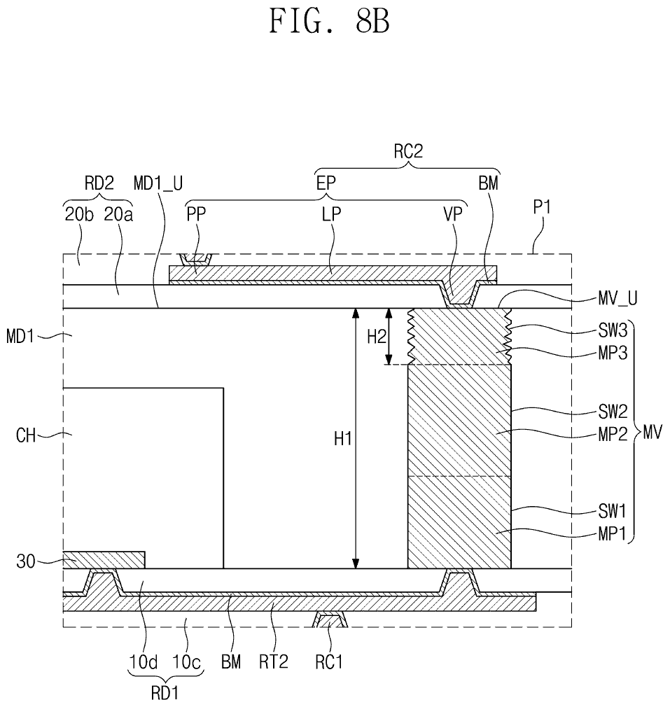

FIG. 8A illustrates a cross-sectional view showing a semiconductor package 1001 according to some embodiments consistent with the present disclosure. FIG. 8B illustrates an enlarged view showing section P1 of FIG. 8A.

Referring to FIGS. 8A and 8B, in a semiconductor package 1001 according to some embodiments, the first substrate RD1 may have a structure different from that shown in FIG. 2. The first substrate RD1 may include first dielectric layers 10a to 10d, under bumps UBM, first substrate inner patterns RC1, and first and second substrate upper patterns RT1 and RT2. The second substrate inner patterns RC2, the first substrate inner patterns RC1, and the first and second substrate upper patterns RT1 and RT2 may each include a via part VP, a line part LP, and a pad part PP. However, unlike the embodiment of FIG. 2, in each of the first substrate inner patterns RC1 and the first and second substrate upper patterns RT1 and RT2, the line part LP and the pad part PP may be positioned beneath the via part VP. The via part VP of each of the first and second substrate upper patterns RT1 and RT2 may have a width that decreases in an upward direction (e.g., in a direction from first substrate RD1 toward second substrate RD2). The via part VP of conductive pads RP3 may have a width that decreases in a downward direction (e.g., in a direction from second substrate RD2 toward first substrate RD1). Each of the first and second substrate upper patterns RT1 and RT2 may be called a redistribution pattern.

The first substrate upper patterns RT1 may be correspondingly in contact with the chip conductive pads 30 of the semiconductor device CH. The second substrate upper patterns RT2 may be correspondingly in contact with bottom surfaces of the mold vias MV. A bottom surface of the semiconductor device CH may be in contact with a top surface of the first substrate RD1. Unlike the embodiment of FIG. 2, neither the first inner connection members IB1 nor the underfill layer UF may be interposed between the semiconductor device CH and the first substrate RD1. Other configurations may be identical or similar to those discussed above.

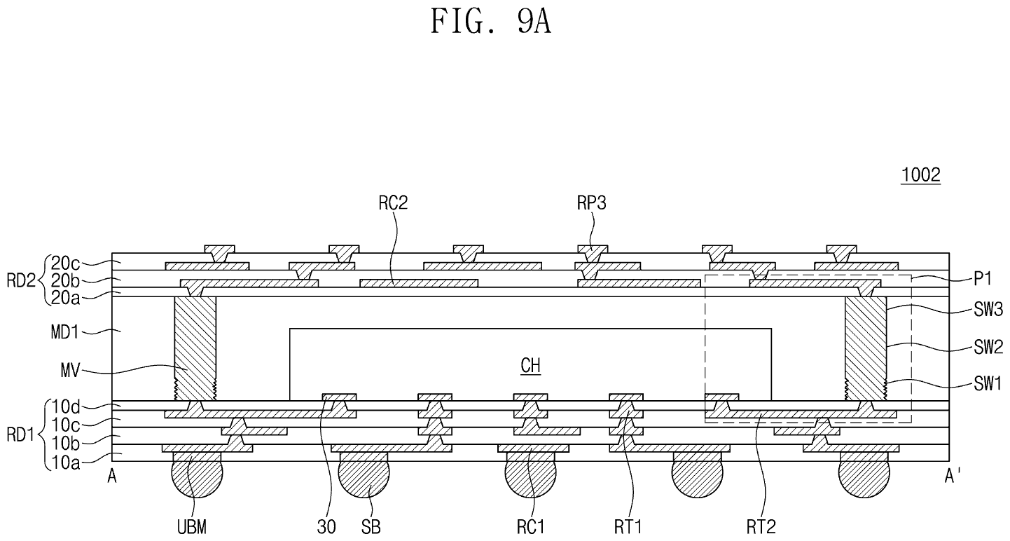

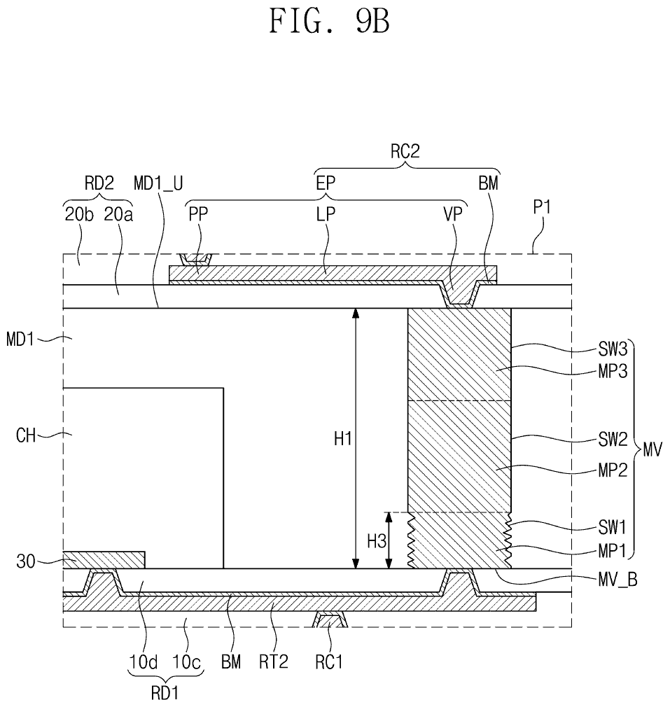

FIG. 9A illustrates a cross-sectional view showing a semiconductor package 1002 according to some embodiments consistent with the present disclosure. FIG. 9B illustrates an enlarged view showing section P1 of FIG. 9A according to some embodiments consistent with the present disclosure.

Referring to FIGS. 9A and 9B, the mold via MV of a semiconductor package 1002 according to some embodiments may have a structure different from that of the mold via MV of the semiconductor package 1001 shown in FIGS. 8A and 8B. The lower sidewall SW1 of the mold via MV according to some embodiments may have a surface roughness greater than that of at least one of the middle sidewall SW2 and the upper sidewall SW3. The surface roughness of the upper sidewall SW3 may be small. Thus, an increased adhesive force may be provided between the first mold layer MD1 and the lower sidewall SW1 of the mold via MV, thereby preventing delamination between the first mold layer MD1 and the lower sidewall SW1 of the mold via MV. The lower sidewall SW1 of the mold via MV may have a third vertical length H3. The third vertical length H3 of the lower sidewall SW1 may correspond to about 1/12 to about 11/12 of the first vertical length H1 of the mold via MV. Other configurations may be identical or similar to those discussed with reference to FIGS. 8A and 8B. In a method of fabricating the semiconductor package 1002 according to some embodiments, the formation of the semiconductor device CH, the first mold layer MD1, and the mold via MV may be followed by the formation of the first substrate RD1 beneath the first mold layer MD1 and the mold via MV. As there is no delamination between the first mold layer MD1 and the mold via MV, the first substrate RD1 may be formed without failure.

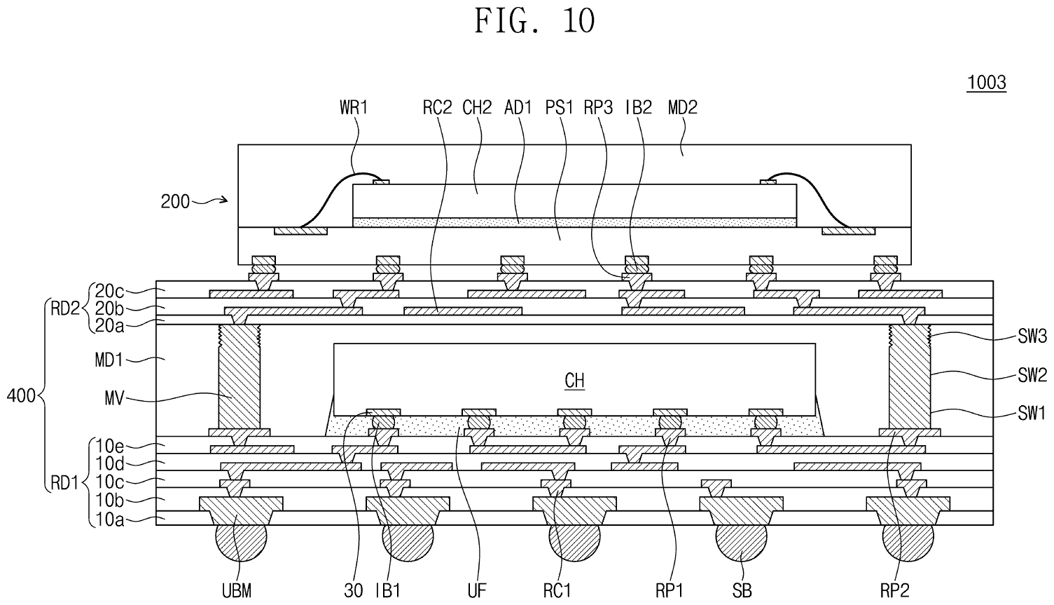

FIG. 10 illustrates a cross-sectional view showing a semiconductor package 1003 according to some embodiments consistent with the present disclosure.

Referring to FIG. 10, a semiconductor package 1003 according to some embodiments may have a package-on-package structure which includes a first sub-semiconductor package 400 and a second sub-semiconductor package 200 mounted on the first sub-semiconductor package 400. The first sub-semiconductor package 400 may have a structure identical or similar to that of the semiconductor package 1000 discussed with reference to FIG. 2, 8A, or 9A.

The second sub-semiconductor package 200 may be bonded through second inner connection members IB2 to the third conductive pads RP3 of the second substrate RD2 in the first sub-semiconductor package 400. The second sub-semiconductor package 200 may include a first sub-package substrate PS1, a second semiconductor device CH2 disposed on the first sub-package substrate PS1, a first adhesion layer AD1 interposed between the first sub-package substrate PS1 and the second semiconductor device CH2, a second mold layer MD2 that covers the first sub-package substrate PS1 and the second semiconductor device CH2, and first wires WR1 that connect the first sub-package substrate PS1 to the second semiconductor device CH2. The first sub-package substrate PS1 may be a double-sided or multi-layered printed circuit board. Alternatively, the first sub-package substrate PS1 may be a redistribution substrate. The second semiconductor device CH2 may be one of an image sensor chip such as CMOS image sensor (CIS), a microelectromechanical system (MEMS) device chip, an application specific integrated circuit (ASIC) chip, and a memory device chip such as Flash memory, DRAM, SRAM, EEPROM, PRAM, MRAM, ReRAM, HBM (high bandwidth memory), and HMC (hybrid memory cube).

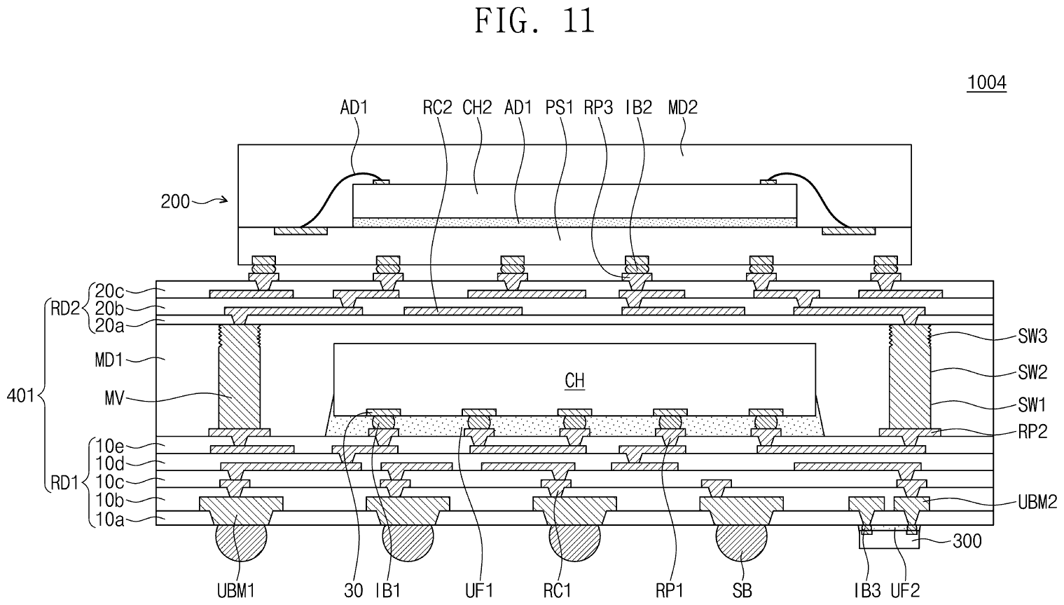

FIG. 11 illustrates a cross-sectional view showing a semiconductor package 1004 according to some embodiments consistent with the present disclosure.

Referring to FIG. 11, a semiconductor package 1004 according to some embodiments may have a package-on-package structure which includes a first sub-semiconductor package 401 and a second sub-semiconductor package 200 mounted on the first sub-semiconductor package 400. The first sub-semiconductor package 401 may have a structure similar to that of the semiconductor package 1000 shown in FIG. 2, 8A, or 9A. A passive device 300 may be bonded to a bottom surface of the first substrate RD1 in the first sub-semiconductor package 401. The first substrate RD1 may include first under bumps UBM1 and second under bumps UBM2. The first under bumps UBM1 and the second under bumps UBM2 may be formed of the same conductive material. A width of each of the second under bumps UBM2 may be less than that of each of the first under bumps UBM1. A height of each of the second under bumps UBM2 may be the same as that of each of the first under bumps UBM1.

The first under bumps UBM1 may be provided thereon with external connection terminals SB bonded thereto. The passive device 300 may be bonded through third inner connection members IB3 to the second under bumps UBM2. The passive device 300 may be a capacitor or a resistor. A first underfill layer UF1 may be interposed between the semiconductor device CH and the first substrate RD1. A second underfill layer UF2 may be interposed between the passive device 300 and the first substrate RD1. Other configurations may be identical or similar to those discussed above with reference to FIG. 10.

In a semiconductor package according to some embodiments consistent with the present disclosure, as an upper sidewall of a mold via has a large surface roughness, an increased adhesive force may be provided between a mold layer and the upper sidewall of the mold via, thereby preventing delamination between the mold layer and the upper sidewall of the mold via. As a result, the semiconductor package may increase in reliability.

In a method of fabricating a semiconductor package according to some embodiments consistent with the present disclosure, when a roughness is formed on an upper sidewall of a mold via, a surface of a first substrate may be covered with a photoresist layer, thereby preventing damage to the surface of the first substrate. In addition, a roughness may be formed on the upper sidewall of the mold via, and an increased adhesive force may be provided between a mold layer and the upper sidewall of the mold via, thereby preventing delamination of the mold via during a grinding process. As a result, process failure may be reduced to increase a yield.

Although the present disclosure describes several embodiments illustrated in the accompanying drawings, it will be understood to those skilled in the art that various changes and modifications may be made without departing from the features of the present disclosure. It will be apparent to those skilled in the art that various substitutions, modifications, and changes may be thereto without departing from the scope of the present disclosure. Various features of the embodiments of FIGS. 1 to 11 may be combined with each other.

What is claimed is:

1. A semiconductor package, comprising:
a first substrate;
a semiconductor device on the first substrate;
a mold layer that covers the first substrate and the semiconductor device;
a second substrate on the mold layer; and
a mold via that penetrates the mold layer and connects the first substrate to the second substrate,
wherein:
the mold via has an upper sidewall and a lower sidewall, and
a surface roughness of the upper sidewall is greater than a surface roughness of the lower sidewall.

2. The semiconductor package of claim 1, wherein:
the mold via further has a middle sidewall between the upper sidewall and the lower sidewall, and
the mold via has a protrusion that laterally protrudes relative to the middle sidewall and the lower sidewall, the protrusion disposed between the middle sidewall and the lower sidewall.

3. The semiconductor package of claim 1, wherein:
the mold via further has a middle sidewall between the upper sidewall and the lower sidewall, and
the middle sidewall is not aligned with the upper sidewall or the lower sidewall.

4. The semiconductor package of claim 3, wherein the surface roughness of the upper sidewall is greater than a surface roughness of the middle sidewall.

5. The semiconductor package of claim 1, wherein a vertical length of the upper sidewall corresponds to about 1/12 to about 11/12 of a vertical length of the mold via.

6. The semiconductor package of claim 1, wherein the first substrate includes:
a plurality of first dielectric layers that are stacked on each other; and
a first conductive pad and a second conductive pad on an uppermost one of the first dielectric layers,
wherein:
the first conductive pad is connected to the semiconductor device,
the second conductive pad is in contact with the mold via,
the first conductive pad has a first width, and
the second conductive pad has a second width greater than the first width.

7. The semiconductor package of claim 1, wherein a top surface of the mold layer is coplanar with a top surface of the mold via.

8. The semiconductor package of claim 1, wherein a surface roughness of a top surface of the mold via is less than the surface roughness of the upper sidewall of the mold via.

9. A semiconductor package, comprising:
a first substrate;
a semiconductor device on the first substrate;
a mold layer that covers the first substrate and the semiconductor device;
a second substrate on the mold layer; and
a mold via that penetrates the mold layer and connects the first substrate to the second substrate,
wherein:
the mold via has an upper sidewall, a middle sidewall, and a lower sidewall, and
the middle sidewall is not aligned with the upper sidewall or the lower sidewall.

10. The semiconductor package of claim 9, wherein a surface roughness of the upper sidewall is greater than a surface roughness of the lower sidewall.

11. The semiconductor package of claim 9, wherein the mold via has a protrusion that laterally protrudes relative to the middle sidewall and the lower sidewall, the protrusion disposed between the middle sidewall and the lower sidewall.

12. The semiconductor package of claim 9, wherein a surface roughness of the upper sidewall is greater than a surface roughness of the middle sidewall.

13. The semiconductor package of claim 9, wherein a vertical length of the upper sidewall corresponds to about 1/12 to about 11/12 of a vertical length of the mold via.

14. The semiconductor package of claim 9, wherein the first substrate includes:
a plurality of first dielectric layers that are stacked on each other; and
a first conductive pad and a second conductive pad on an uppermost one of the first dielectric layers,
wherein:
the first conductive pad is connected to the semiconductor device,
the second conductive pad is in contact with the mold via,
the first conductive pad has a first width, and
the second conductive pad has a second width greater than the first width.

15. A semiconductor package, comprising:
a first redistribution substrate;
a semiconductor device on the first redistribution substrate;
a mold layer that covers the first redistribution substrate and the semiconductor device;
a second redistribution substrate on the mold layer; and
a mold via that penetrates the mold layer and connects the first redistribution substrate to the second redistribution substrate,
wherein:
the first redistribution substrate includes:
a plurality of first redistribution dielectric layers that are stacked on each other; and
a first conductive pad and a second conductive pad on an uppermost one of the first redistribution dielectric layers,
the first conductive pad is connected to the semiconductor device,
the second conductive pad is in contact with the mold via,
the first conductive pad has a first width,
the second conductive pad has a second width greater than the first width, and
the second redistribution substrate includes:
a plurality of second redistribution dielectric layers that are stacked on each other; and
a second redistribution pattern that penetrates a lowermost one of the second redistribution dielectric layers and is in contact with the mold via.

16. The semiconductor package of claim 15, wherein:
the mold via has an upper sidewall and a lower sidewall, and
a surface roughness of the upper sidewall is greater than a surface roughness of the lower sidewall.

17. The semiconductor package of claim 16, wherein:
the mold via further has a middle sidewall between the upper sidewall and the lower sidewall, and
the mold via has a protrusion that laterally protrudes relative to the middle sidewall and the lower sidewall, the protrusion disposed between the middle sidewall and the lower sidewall.

18. The semiconductor package of claim 16, wherein:
the mold via further has a middle sidewall between the upper sidewall and the lower sidewall, and
the middle sidewall is not aligned with the upper sidewall or the lower sidewall.

19. The semiconductor package of claim 18, wherein the surface roughness of the upper sidewall is greater than a surface roughness of the middle sidewall.

20. The semiconductor package of claim 16, wherein a vertical length of the upper sidewall corresponds to about 1/12 to about 11/12 of a vertical length of the mold via.
